(19) United States
(12) Patent Application Publication
(10) Pub. No.: US 2025/0357245 A1
(43) Pub. Date: Nov. 20, 2025

(54) METHOD FOR PRODUCING A POWER MODULE WITH SINTERED HEAT SINK

(71) Applicant: Robert Bosch GmbH, Stuttgart (DE)

(72) Inventors: Alexander Baer, Reutlingen (DE); Erik Sueske, Reutlingen (DE); Stefan Kaessner, Radolfzell (DE); Steffen Orso, Reutlingen (DE); Ulrich Kessler, Stuttgart (DE)

(21) Appl. No.: 18/663,477

(22) Filed: May 14, 2024

(30) Foreign Application Priority Data
Mar. 23, 2023 (DE) 10 2023 202 634.1

(51) Int. Cl. H01L 23/367; H01L 23/00; H01L 23/373

(52) U.S. Cl. CPC H01L 23/3677; H01L 23/3735; H01L 24/83; H01L 2224/8384

(57) ABSTRACT

A production method for producing a power module with a heat sink using a sintering process. In order to use the method to provide a power module that has detachment-resistant thermal bonding of the heat sink even at high temperatures, and/or under high thermomechanical loads, and thus has reliable cooling, and in this way also increased power density and/or service life and/or operational safety. In the method, a specific sintering pressure is applied using a sintering stamp to an arrangement including the heat sink, a sintered connection layer applied to the heat sink, and a circuit carrier applied to the sintered connection layer). A power module is also described.

### FIELD

The present invention relates to a production method for producing a power module having a heat sink by means of a sintering process, and to such a power module.

### BACKGROUND INFORMATION

Power modules having power semiconductors are used, inter alia, in energy converters such as converters and/or inverters and/or power switches and/or motor control units, for example in electrically powered vehicles.

During the operation of power modules, for example during the conversion of energy in converters and/or inverters, high temperatures, in particular of over 230° C., possibly even briefly of over 400° C., and high thermomechanical loads and, for example, also high power losses can occur.

To avoid overheating, power modules are therefore often cooled. The cooler bonding is realized, inter alia, by solder connections. However, when using soldered connections, the operating temperature of the power module can be limited by the melting temperature of the soldered connection. Typical soft solders generally have, for example, a melting temperature in a range of 210° C. to 260° C., although solders with a high lead content can also have a melting temperature of up to approx. 300° C. In addition, soldered connections can only withstand limited thermomechanical stress. In addition, soldered connections generally have a rather moderate thermal conductivity, typically approximately 50 W/mk at 25° C., and/or must be formed with comparatively high layer thicknesses, typically in the range of 200 μm to 300 μm, in order to sufficiently fulfill service life requirements.

German Patent Application No. DE 10 2014 221 142 A1 relates to a module with sintered bonding.

### SUMMARY

The present invention relates to a production method for producing a power module with a heat sink, for example for a converter and/or inverter and/or power switch and/or motor control unit, for example for a vehicle, for example an electrically powered vehicle, by means of a sintering process. According to an example embodiment of the present invention, in the method, a specific sintering pressure, for example at a specific sintering temperature and/or for a specific sintering period, is applied to an arrangement consisting of the heat sink, a sintered connection layer applied to the heat sink, and a circuit carrier applied to the sintered connection layer, in particular by means of a sintering stamp.

A sintered connection can be understood in particular as a connection which can be formed or is formed by sintering metal particles, for example silver and/or copper particles, for example at an elevated temperature, in particular below the melting temperature, and for example under increased pressure, for example in a range from 5 MPa to 30 MPa, preferably in a range from 10 or 15 to 25 MPa.

By means of the method, the sintered connection layer can be sintered in a simple manner and the heat sink can be connected to the circuit carrier via the sintered connection layer.

Since sintered connections have a significantly higher melting temperature than soldered connections, for example silver sintered connections can have a melting point of approximately 962° C. and copper sintered connections can even have a melting point of approximately 1085° C., through the use of a sintered connection layer, for example instead of a soldered connection layer, a detachment-resistant connection of the heat sink to the circuit carrier can be achieved, even at high temperatures and/or under high thermomechanical loads, and in this way the power density and/or the service life and/or the operational safety of the power module can be further increased, in particular even at high temperatures and/or under high thermomechanical loads. In addition, sintered connections can advantageously have a comparatively high thermal conductivity, for example on the order of >100 W/mK at room temperature, and can be realized in layer thicknesses of approximately 10 to 100 μm. Therefore, the sintered connection layer can advantageously be used not only for electrical bonding, but also advantageously for thermal bonding of the heat sink to the circuit carrier, and in this way, for example, power modules on the circuit carrier can be deheated or cooled. This is also an advantageous way of protecting the assembly and connection technology in the event of short-term special operating conditions at high temperatures, for example in the event of a short circuit. Advantageously, costly and/or assembly- and/or connection-restricting measures for limiting the temperature and/or reducing the temperature load, for example in the form of a reduction in resistance by increasing the active semiconductor area, can also be dispensed with. Thus, the use of a sintered connection to bond the heat sink to the circuit carrier can advantageously eliminate all the limitations of soldered connections explained at the outset.

According to an example embodiment of the present invention, by means of the sintering stamp, the sintering pressure can advantageously be introduced to achieve high thermal conductivity and high load-bearing capacity.

As a whole, the method of the present invention can thus advantageously produce a power module that has detachment-resistant thermal bonding of the heat sink to the circuit carrier even at high temperatures, for example above 230° C., and/or under high thermomechanical loads, and thus has reliable cooling and in this way also increased power density and/or service life and/or operational safety.

In one example embodiment of the present invention, power module components are already applied to the circuit carrier before the sintering pressure is applied by the sintering stamp. The power module components can be, for example, at least one power semiconductor and/or at least one electrical contact element, for example at least one bonding wire, for example made of aluminum, and/or at least one, in particular planar, electrical cover contact element, for example made of copper and/or silver, and/or at least one casting compound and/or at least one further sintered connection layer, for example for electrical bonding, in particular for electrical and thermal bonding, of the at least one power semiconductor and/or the at least one electrical contact element. In this way, the production of the power module can be advantageously simplified. Advantageously, this makes it possible to sinter both the sintered connection layer between the heat sink and the circuit carrier and other sintered connection layers on the circuit carrier in one process step.

In a further embodiment of the present invention, the sintering stamp has a cavity that can be filled with a hydrostatic medium.

In particular, the sintering stamp can be placed on the heat sink and/or circuit carrier, for example, in such a way that the sintered connection layer and optionally power module components (already) applied to the circuit carrier is or are accommodated in the cavity. The cavity can be closed by the heat sink and/or the circuit carrier, for example. The specific sintering pressure can be exerted on the arrangement in particular by filling the cavity with a hydrostatic medium, in particular a fluid, for example an oil, for example a silicone and/or Teflon oil, with a specific hydrostatic pressure. In particular, the specific hydrostatic pressure can substantially correspond to the specific sintering pressure. In this way, the topology or topography can advantageously be evened out when applying the sintering pressure. This embodiment is therefore particularly suitable for strong topologies/topographies. This embodiment makes it particularly advantageously possible to apply power module components to the circuit carrier before the sintering pressure is applied by the sintering stamp. In addition, this can advantageously simplify the production of the power module, in particular because the method advantageously makes it possible to sinter both the sintered connection layer between the heat sink and the circuit carrier and other sintered connection layers on the circuit carrier in one process step. The hydrostatic medium can, for example, be heated to a or the specific sintering temperature.

In another, alternative or additional embodiment of the present invention, the sintering stamp has a stamp portion having a topography which is adapted to the topography of the circuit carrier and the sintered connection layer and optionally of power module components (already) applied to the circuit carrier. For example, the topography of the stamp portion can be a, for example precisely fitting, positive image of the topography of the circuit carrier and the sintered connection layer and of optional power module components (already) applied to the circuit carrier, for example in the form of a negative image. In this way, the topology or topography can advantageously also be evened out when applying the sintering pressure. Therefore, this embodiment is also particularly suitable for strong topologies/topographies. This embodiment also advantageously makes it possible to apply power module components to the circuit carrier before the sintering pressure is applied by the sintering stamp. In addition, this can also advantageously simplify the production of the power module, in particular because the method advantageously makes it possible to sinter both the sintered connection layer between the heat sink and the circuit carrier and other sintered connection layers on the circuit carrier in one process step. The stamp portion can, for example, be heated to a specific sintering temperature.

In a further, alternative embodiment of the present invention, the sintering stamp has a flat stamp surface or a flat stamp portion. The circuit carrier can (still) be free of power module components before and/or during the application of the sintering pressure by the sintering stamp, or power module components can already be applied to the circuit carrier before the application of the sintering pressure by the sintering stamp, which components have a low, for example at least substantially flat, topology or topography. The flat stamp surface or the flat stamp portion can also be heated to a specific sintering temperature. In this way, the method can be advantageously performed with a simple tool.

In a further embodiment of the present invention, the sintered connection layer is only formed in at least one portion between the heat sink and the circuit carrier, which portion is designed for thermal bonding of the circuit carrier and optionally power module components (already) applied or to be applied thereto. For example, this at least one portion can ensure thermal conductivity. In this way, both a thermal and mechanical, temperature-stable bonding of the heat sink to the circuit carrier can advantageously be realized and in this way a high power density and/or service life and/or operational safety can be achieved.

In one configuration of this example embodiment of the present invention, at least a portion of another layer is also formed between the heat sink and the circuit carrier. The other layer can be designed for a different functionality and need not, for example, be designed for temperature-resistant, thermal and mechanical bonding. For example, the other layer can be a solder connection layer, for example made of a soft solder, such as a tin-based solder, or a diffusion solder, for example based on a copper-tin intermetallic. Such a configuration can advantageously reduce the load on the power module during mounting on the heat sink and/or better even out mechanical loads in the module locally due to the small bonding surface of the sintered connection layer.

In a further embodiment of the present invention, the specific sintering pressure and/or the specific hydrostatic pressure is in a range from 5 MPa to 30 MPa, preferably in a range from 15 to 25 MPa. This has proven to be advantageous for the sintering of sintered connections.

The specific sintering temperature can be in the range from 200° C. to 300° C., preferably in the range from 240° C. to 280° C., for example.

The specific sintering period can, for example, be in a range from 60 s to 300 s, preferably in a range from 120 s to 200 s.

The heat sink can, for example, comprise ceramic and/or copper and/or aluminum and/or an aluminum alloy.

In a further embodiment of the present invention, the heat sink has a noble metal coating, for example made of silver and/or copper, on one side, to which the sintered connection layer is applied. In this way, both the thermal bonding and the adhesion of the sintered connection layer can be advantageously increased, and in this way the power density and/or service life and/or operational safety of the power module can be further increased.

The heat sink can, for example, be designed and/or configured as a simple metal plate, as a fin and/or pin-fin structure and/or as a closed heat sink.

In a further embodiment of the present invention, the sintered connection layer comprises silver and/or copper or is made thereof. This has proven to be particularly advantageous for the reasons already explained.

In a further embodiment of the present invention, the sintered connection layer has an average layer thickness in the range from 50 μm to 200 μm, for example approximately 100 μm. In this way—while achieving a high power density and/or service life and/or operational safety of the power module—a reduced height of the power module can advantageously be realized and/or material costs can be reduced.

In a further configuration of the present invention, the sintered connection layer comprises silver and/or copper or is made thereof.

In a further configuration of the present invention, the circuit carrier has at least one metal layer, for example made of copper. Copper has proven to be advantageous for electrical and electronic applications and can provide chemical bonding for casting compounds through oxide formation. In this way, an increase in the power density and/or service life and/or operational safety of the power module can be advantageously achieved.

In a further configuration of the present invention, the circuit carrier also has an insulating layer. For example, the insulating layer can comprise an inorganic, in particular ceramic, material and/or a plastics material. In particular, the insulating layer can be made of an inorganic, in particular ceramic, material or a plastics material. For example, the insulating layer can comprise a nitridic and/or carbidic and/or oxidic material, for example silicon nitride (Si₃N₄) and/or aluminum nitride (AlN) and/or boron nitride (BN) and/or silicon carbide (Sic) and/or aluminum oxide (Al₂O₃) and/or magnesium oxide (MgO) and/or silicon oxide (SiO₂) and/or beryllium oxide (BeO).

For example, the insulating layer can be made of an inorganic, in particular ceramic, for example nitridic, material, for example silicon nitride (Si₃N₄) and/or aluminum nitride (AlN) and/or boron nitride (BN), or from a plastics material which contains at least one polymer and, for example, furthermore at least one inorganic, in particular ceramic, for example oxidic and/or nitridic and or carbidic filler, for example aluminum oxide (Al₂O₃) and/or magnesium oxide (MgO) and/or silicon oxide (SiO₂) and/or beryllium oxide (Be), and/or silicon nitride (Si₃N₄) and/or aluminum nitride (AlN) and/or boron nitride (BN) and/or silicon carbide (Sic).

The circuit carrier can be a power substrate, for example.

The circuit carrier can, for example, be an AMB (Active Metal Brazing), for example with an inorganic, in particular ceramic, for example nitridic, insulating layer, for example made of silicon nitride (Si₃N₄) and/or aluminum nitride (AlN) and/or boron nitride (BN), and a metal layer soldered thereon. The insulating layer can also be used here as a carrier layer.

The circuit carrier can, for example, also be a DBC (Direct Bond Copper), for example with an inorganic, in particular ceramic, for example nitridic or oxidic, insulating layer, for example made of aluminum nitride (AlN) and/or silicon nitride (Si₃N₄) and/or boron nitride (BN) and/or aluminum oxide (Al₂O₃), and a metal layer, in particular copper or aluminum, applied thereon. The insulating layer can also be used here as a carrier layer if necessary.

However, the circuit carrier can also be an IMS (Insulated Metallic Substrate), for example. In particular, the insulating layer can be made from a plastics material and comprise, for example, at least one polymer and, for example, in addition at least one inorganic, in particular ceramic, for example oxidic and/or nitridic and/or carbidic, filler, for example aluminum oxide (Al₂O₃) and/or magnesium oxide (MgO) and/or silicon oxide (SiO₂) and/or beryllium oxide (BeO), and/or silicon nitride (Si₃N₄) and/or aluminum nitride (AlN) and/or boron nitride (BN) and/or silicon carbide (Sic). The metal layer can be applied to the insulating layer in the form of a foil, for example. The insulating layer can be supported by a carrier layer, for example made of aluminum.

In one configuration of the present invention, the insulating layer has on at least one side at least one portion coated with at least one portion of the metal layer, and at least one portion without a metal layer. By means of the metal layer-free portions, on the one hand, an electrical and possibly also thermal decoupling of components of the power module can be achieved. Due to the fact that the insulating layer has metal layer-free portions and the material of the insulating layer can have better adhesion properties and, in particular, can have a higher proportion of components suitable for chemical bonding of a casting compound applied thereto, for example in the form of oxidic impurities in nitridic and/or carbidic materials and/or oxides in oxidic materials and/or functional groups in organic, in particular polymeric, materials, than the metal layer, by means of the metal layer-free portions of the insulating layer, an improved adhesion and in particular also a further improved chemical bonding of a casting compound applied to the metal layer-free portions of the insulating layer can be achieved.

Advantageously, epoxy-based and/or other casting compounds, for example hard casting compounds, can form chemical bonds in this case, for example with oxides of the metal layer-free portions of the insulating layer, and in this way a particularly stable and in particular particularly detachment-resistant chemical bonding of a casting compound applied thereto can be achieved. The at least one metal layer-free portion of the insulating layer can for example also be free of sintered connection layers and/or power semiconductors. The insulating layer can have a smaller thickness than the metal layer.

In a further configuration of the present invention, the at least one power semiconductor comprises or is a wide-band-gap semiconductor, such as a SiC power semiconductor and/or GaN power semiconductor. Such power semiconductors can advantageously remain stable even at high temperatures and/or under special operating conditions, so that in this way the power density and/or the service life and/or the operational safety can be further increased, in particular even at high temperatures and/or under high thermomechanical loads. With wide-band-gap semiconductors, the functionality-especially with short pulses and/or when briefly exceeding 400° C.—can advantageously still remain.

In a further configuration of the present invention, the at least one power semiconductor and/or the electrical contact element is cast with a casting compound. Casting with the casting compound can advantageously protect and/or insulate the at least one power semiconductor from environmental influences and/or media. In addition, mechanical stresses can be absorbed by casting with the casting compound, in particular with a hard casting compound. In this way, the service life and/or operational safety of the power module can be further increased.

The casting compound can also advantageously increase the power density of the power module, which can have an advantageous effect on the economic implementation of energy converters and/or in the field of electromobility, for example.

In a further configuration of the present invention, the casting compound is also applied to the at least one metal layer-free portion of the insulating layer. In this way, advantageously, a particularly good adhesion of the casting compound, for example via oxides in this portion, can be achieved and thus a significantly improved service life and/or operational safety of the power module can be achieved and, in particular, the power density of the power module can be further increased, which can have an advantageous effect, for example, on an economical implementation of energy converters and/or in the field of electromobility.

In a further configuration of the present invention, the casting compound is a hard casting compound. A hard casting compound can advantageously absorb mechanical stresses and thus further increase the service life and/or operational safety of the power module. In addition, the power density of the power module can be further increased, which can have an advantageous effect on the economic implementation of energy converters and/or in the field of electromobility, for example. The hard casting compound can be an organic or ceramic hard casting compound, for example. For example, the casting compound, in particular the hard casting compound, can be organic-based and/or ceramic-based. For example, the casting compound, in particular the hard casting compound, can be epoxy-based or ceramic. In this way, chemical bonding of the casting compound, in particular the hard casting compound, to the oxides of the layers can be achieved.

In a further configuration of the present invention, the circuit carrier has a first metal layer on a first side and a second metal layer on a second side, in particular opposite the first side. In particular, the first metal layer and the second metal layer can be of the same or different design as the metal layer described above.

In a further configuration of the present invention, the circuit carrier has an insulating layer, with the first metal layer being applied to a first side of the insulating layer and the second metal layer being applied to a second side of the insulating layer, in particular opposite the first side. The circuit carrier can be an AMB (Active Metal Brazing) or DBC (Direct Bond Copper), for example with an inorganic, in particular ceramic, for example nitridic, insulating layer, for example made of silicon nitride (Si₃N₄) and/or aluminum nitride (AlN) and/or boron nitride (BN) and/or aluminum oxide (Al₂O₃), and a metal layer applied thereon. The insulating layer can also be used here as a carrier layer.

In another configuration of the present invention, the circuit carrier has a first insulating layer and a second insulating layer. The first and second insulating layers can be designed and/or formed in the same or different ways as the insulating layer described above. In particular, the first metal layer can be applied to the first insulating layer and the second metal layer to the second insulating layer. The circuit carrier can have a carrier layer, for example made of aluminum, between the first and second insulating layers. The circuit carrier can be an IMS (Insulated Metallic Substrate), for example. In particular, the first and second insulating layers can be formed from a plastics material and, for example, comprise at least one polymer and, for example, furthermore at least one inorganic, in particular ceramic, for example oxidic and/or nitridic and/or carbidic, filler, for example aluminum oxide (Al₂O₃) and/or magnesium oxide (MgO) and/or silicon oxide (SiO₂) and/or beryllium oxide (BeO), and/or silicon nitride (Si₃N₄) and/or aluminum nitride (AlN) and/or boron nitride (BN) and/or silicon carbide (SiC). The metal layers can each be applied to the insulating layers in the form of a foil, for example.

With regard to further technical features and advantages of the method according to the present invention, reference is hereby explicitly made to the explanations in connection with the power module produced according to the present invention and the power module according to the present invention as well as to the figures and the description of the figures.

A further object of the present invention is a power module that is produced by a method according to the present invention. With regard to further technical features and advantages of the power module produced according to the present invention, reference is hereby explicitly made to the explanations in connection with the method according to the present invention and the power module according to the present invention as well as to the figures and the description of the figures.

Furthermore, the present invention relates to a power module, for example a power module produced according to the present invention and/or a power module produced by a method according to the present invention, which has a heat sink, a sintered connection layer applied to the heat sink, and a circuit carrier applied to the sintered connection layer.

In particular, the sintered connection layer can only be formed in at least one portion between the heat sink and the circuit carrier, which portion is designed for the thermal bonding of the circuit carrier and power module components applied or to be applied thereto. In this way, for example, thermal conductivity can be ensured.

In one embodiment of this, at least a portion of another layer, for example a solder connection layer, for example made of a soft solder, for example a tin-based solder, or a diffusion solder, for example based on a copper-tin intermetallic, is also formed between the heat sink and the circuit carrier.

With regard to further technical features and advantages of the power module according to the present invention, reference is hereby explicitly made to the explanations in connection with the method according to the present invention and the power module produced according to the present invention, as well as to the figures and the description of the figures.

### BRIEF DESCRIPTION OF THE DRAWINGS

Further advantages and advantageous configurations of the subjects according to the present invention are illustrated by the figures and explained in the following description. It is to be noted that the figures are only descriptive in character and are not intended to limit the present invention in any way.

FIG. 1 is a schematic cross-section of an embodiment of a method according to the present invention with a sintering stamp having a cavity for a hydraulic medium.

FIG. 2 is a schematic cross-section through an embodiment of a method according to the present invention with a sintering stamp having a stamp portion with an adapted topography or topology.

FIG. 3 is a schematic cross-section through an embodiment of a method according to the preset invention with a sintering stamp having a flat stamp surface or a flat stamp portion.

FIG. 4 is a schematic cross-section through an embodiment of a power module produced according to the present invention.

FIG. 5 is a schematic cross-section through an embodiment of a power module produced according to the present invention and/or according to the present invention with a sintered connection layer formed only in a portion between the heat sink and the circuit carrier.

### DETAILED DESCRIPTION OF EXAMPLE EMBODIMENTS

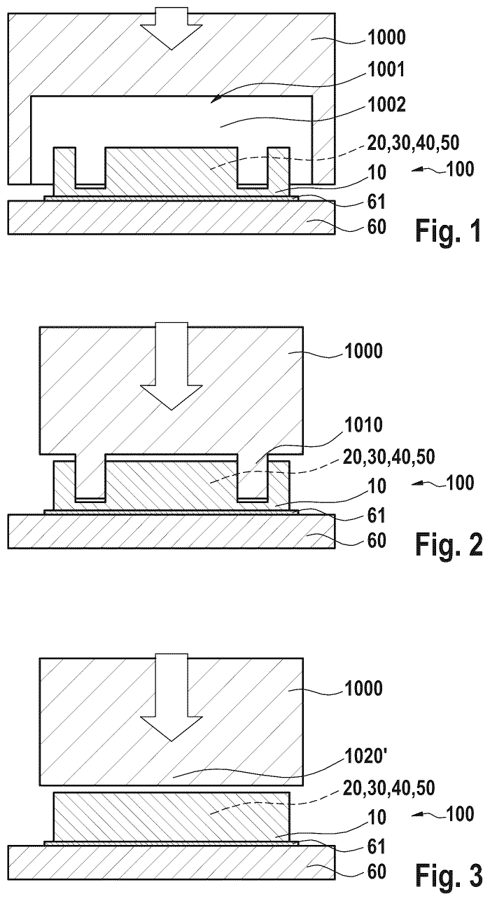

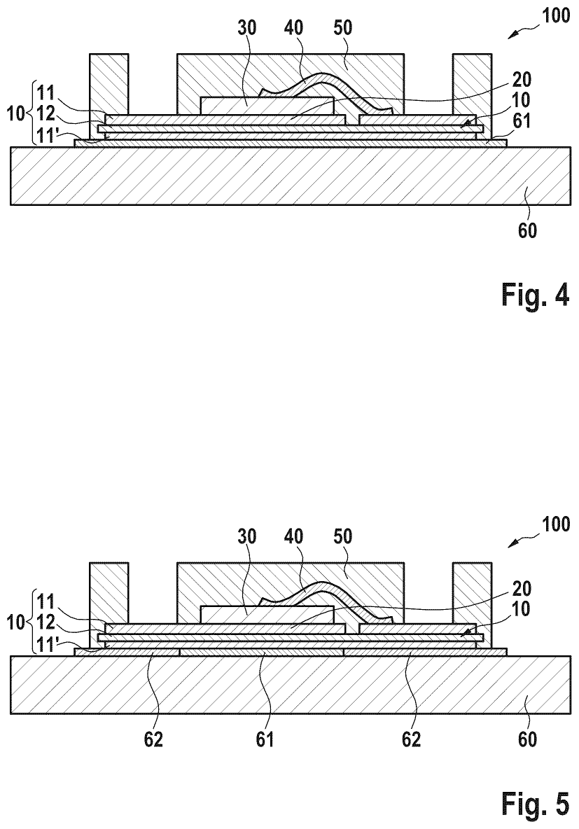

FIGS. 1 to 3 show three different embodiments of a production method according to the present invention for producing a power module 100 having a heat sink 60 by means of a sintering process, in which a specific sintering pressure, for example at a specific sintering temperature and/or for a specific sintering period, is applied to an arrangement 60, 61, 10 consisting of the heat sink 60, a sintered connection layer 61 applied to the heat sink 60, and a circuit carrier 10 applied to the sintered connection layer 61, by means of a sintering stamp 1000. The dashed reference line in FIGS. 1 to 3 indicates that before the sintering pressure is applied by the sintering stamp 1000, power module components 20, 30, 40, 50, for example at least one power semiconductor 30 and/or at least one electrical contact element 40 and/or at least one casting compound 50 and/or at least one further sintered connection layer 20 can already be applied to the circuit carrier 10, which components are not shown in more detail in FIGS. 1 to 3, but are illustrated by way of example in FIGS. 4 and 5.

FIG. 1 illustrates an embodiment of the method in which the sintering stamp 1000 has a cavity 1001 that can be filled with a hydrostatic medium 1002. The sintering stamp 1000 is placed on the heat sink 61 in such a way that the sintered connection layer 61 and the power module components 20, 30, 40, 50 already applied to the circuit carrier 10 are accommodated in the cavity 1001. FIG. 1 shows that the cavity 1001 is closed by the heat sink 61. The specific sintering pressure is exerted on the arrangement 60, 61, 10 by filling the cavity 1001 with a hydrostatic medium 1002, in particular an oil, at a specific hydrostatic pressure. The hydrostatic medium 1002 can also be heated to the specific sintering temperature, for example. In this way, the specific sintering pressure and, for example, the specific sintering temperature can be advantageously achieved in a homogeneous manner that is gentle on the power module components.

FIG. 2 illustrates a further embodiment of the method, in which the sintering stamp 1000 has a stamp portion 1010 having a topography which is adapted, in particular with a precise fit, to the topography of the circuit carrier 10 and the sintered connection layer 61 and of power module components 20, 30, 40, 50 already applied to the circuit carrier 10. FIG. 2 illustrates that the topography of the stamp portion 1010 is a positive image of the topography of the circuit carrier 10 and the sintered connection layer 61 and the power module components 20, 30, 40, 50 already applied to the circuit carrier 10, which form a negative image, and engages in the topography of the circuit carrier 10 and the sintered connection layer 61 and the power module components 20, 30, 40, 50 already applied to the circuit carrier 10. The stamp portion 1010 can also be heated to the specific sintering temperature, for example. In this way, the specific sintering pressure and, for example, the specific sintering temperature can be advantageously achieved in a homogeneous manner that is gentle on the power module components. Through a non-precisely fitting, but rather spaced, cavity-forming configuration of the stamp portion 1010, this embodiment can also be combined with the embodiment shown in FIG. 1.

FIG. 3 shows a further embodiment of the method, in which the sintering stamp 1000 has a flat stamp surface or a flat stamp portion 1020′. The circuit carrier 10 can either be (still) free of power module components before and/or during the application of the sintering pressure by the sintering stamp 1000, or—as shown in FIG. 3-power module components 20, 30, 40, 50 can already be applied to the circuit carrier 10 before the application of the sintering pressure by the sintering stamp 1000, which components, however, have a low, for example at least substantially flat, topology or topography. The stamp surface 1020′ or the stamp portion 1010 can also be heated to the specific sintering temperature, for example.

FIG. 4 shows a schematic cross-section through an embodiment of a power module 100 produced according to the present invention, for example for a converter, inverter and/or power switch, for example for an electrically powered vehicle, which has a heat sink 60, a sintered connection layer 61 applied to the heat sink 60, and a circuit carrier 10 applied to the sintered connection layer 61. The sintered connection layer 61 can in particular comprise silver and/or copper or be made therefrom. For example, the sintered connection layer 61 can have an average layer thickness in a range of 50 μm to 200 μm, for example of approximately 100 μm.

FIG. 4 also shows that the circuit carrier 10 has a first metal layer 11, an insulating layer 12, and a second metal layer 11′.

The circuit carrier 10 with the second metal layer 11′ is applied to the sintered connection layer 61 on the heat sink 60.

FIG. 4 illustrates that the insulating layer 12 has on one side a first portion coated with a first portion of the first metal layer 11, and a second portion coated with a second portion of the first metal layer 11, and a metal layer-free portion. A power semiconductor 30, for example a wide-band-gap semiconductor such as a SiC or GaN power semiconductor, is applied to the first portion of the first metal layer 11 of the circuit carrier 10, for example via a further sintered connection layer 20 which is not shown in detail in FIGS. 4 and 5. An electrical contact element 40, for example a bonding wire, for example made of aluminum, is applied to the power semiconductor 30, which bonding wire electrically connects the power semiconductor 30 to the second portion of the first metal layer 11 of the circuit carrier 10.

FIG. 4 also shows that the power semiconductor 30 and the electrical contact element 40 are cast with a casting compound 50. The casting compound 50 can be in particular a hard casting compound. FIG. 1 shows that the casting compound 50 is also applied to the metal-free portion of the insulating layer 12.

The embodiment shown in FIG. 5 differs substantially from the embodiment shown in FIG. 4 in that the sintered connection layer 61 is only formed in at least one portion between the heat sink 60 and the circuit carrier 10, which portion is designed for thermal bonding of the circuit carrier 10 and power module components 20, 30, 40, 50, in particular power semiconductors 30, applied thereto. Furthermore, at least a portion of another layer 62, for example a solder connection layer, for example made of a soft solder, for example a tin-based solder, or a diffusion solder, for example based on a copper-tin intermetallic, is formed between the heat sink 60 and the circuit carrier 10.

1-11. (canceled)

12. A production method for producing a power module having a heat sink using a sintering process, the method comprising:
applying a specific sintering pressure, using a sintering stamp, to an arrangement including the heat sink, a sintered connection layer applied to the heat sink, and a circuit carrier applied to the sintered connection layer.

13. The method according to claim 12, wherein at least one power semiconductor and/or at least one electrical contact element and/or at least one casting compound and/or at least one further sintered connection layer, are applied to the circuit carrier before the sintering pressure is applied by the sintering stamp.

14. The method according to claim 12, wherein the sintering stamp has a cavity that can be filled with a hydrostatic medium, wherein the sintering stamp is placed on the heat sink and/or the circuit carrier in such a way that the sintered connection layer are accommodated in the cavity, wherein the cavity is closed by the heat sink and/or by the circuit carrier, wherein the specific sintering pressure is exerted on the arrangement by filling the cavity with the hydrostatic medium at a specific hydrostatic pressure, and wherein the hydrostatic medium is heated to a specific sintering temperature.

15. The method according to claim 12, wherein the sintering stamp includes a stamp portion having a topography which is adapted to a topography of the circuit carrier and the sintered connection layer, and wherein the stamp portion is heated to a specific sintering temperature.

16. The method according to claim 12, wherein the sintering stamp has a flat stamp surface or a flat stamp portion, wherein: (i) the circuit carrier is free of power module components before and/or during the application of the sintering pressure by the sintering stamp, or (ii) power module components are already applied to the circuit carrier before the application of the sintering pressure by the sintering stamp, which components have an at least substantially flat, topology or topography, and wherein the flat stamp surface or the flat stamp portion is heated to a specific sintering temperature.

17. The method according to claim 12, wherein the sintered connection layer is formed only in at least one portion between the heat sink and the circuit carrier, which portion is configured for thermal bonding of the circuit carrier and power module components applied or to be applied there to the circuit carrier, wherein at least one portion of another layer including a solder connection layer, is also formed between the heat sink and the circuit carrier.

18. The method according to claim 12, wherein the specific sintering pressure and/or a specific hydrostatic pressure is in a range from 5 MPa to 30 MPa.

19. The method according to claim 12, wherein the heat sink has a noble metal coating on a side to which the sintered connection layer is applied.

20. The method according to claim 12, wherein: (i) the sintered connection layer includes silver and/or copper, and/or (ii) the sintered connection layer has an average layer thickness in a range from 50 μm to 200 μm.

21. A power module which is produced by applying a specific sintering pressure, using a sintering stamp, to an arrangement including the heat sink, a sintered connection layer applied to the heat sink, and a circuit carrier applied to the sintered connection layer.

22. The power module according to claim 10, wherein the power module comprises the heat sink, the sintered connection layer applied to the heat sink, and the circuit carrier applied to the sintered connection layer, wherein the sintered connection layer is formed only in at least one portion between the heat sink and the circuit carrier, which is configured for thermal bonding of the circuit carrier and power module components applied or to be applied thereto, wherein at least a portion of another layer including a solder connection layer is also formed between the heat sink and the circuit carrier.
